(19) United States
(12) Patent Application Publication
(10) Pub. No.: US 2010/0148312 A1
(43) Pub. Date: Jun. 17, 2010

(54) REINFORCED SMART CARDS & METHODS OF MAKING SAME

(75) Inventor: MATTHEW JUNG, Seoul (KR)

Correspondence Address: TROUTMAN SANDERS LLP;5200 BANK OF AMERICA PLAZA, 600 PEACHTREE STREET, N.E., SUITE 5200, ATLANTA, GA, 30308-2216, US

(73) Assignee: IVI SMART TECHNOLOGIES, INC., New York, NY (US)

(21) Appl. No.: 12/639,976

(22) Filed: Dec. 16, 2009

Related U.S. Application Data
(60) Provisional application No. 61/138,051, filed on Dec. 16, 2008.

(51) Int. Cl. H01L 23/58; H01L 21/302

(52) U.S. Cl. 257/619; 438/464; 257/E21.214; 257/E23.194

(57) ABSTRACT

Reinforced smart cards with and methods of making an integrated circuit chip for smart are disclosed. In some embodiments, a method includes generally providing an integrated circuit wafer including a plurality of integrated circuits, providing a stiffener, attaching the stiffener top surface to the wafer bottom surface, and physically separating integrated circuits. The wafer can be substantially disc-shaped with a wafer perimeter. Integrated circuits can be disposed on the wafer's top surface, and the wafer's bottom surface can span a wafer bottom area. The stiffener can have a top surface spanning an area corresponding to a circuitry portion of the wafer's top surface (where integrated circuits can be disposed). The stiffener's can be applied to the wafer's bottom surface to form a wafer/stiffener assembly. Integrated circuits of the wafer/stiffener assembly can be separated by removing wafer material between integrated circuits and stiffener material between regions of the stiffener underlying the integrated circuits. Other aspects, features, and embodiments are claimed and disclosed.

### CROSS REFERENCE TO RELATED APPLICATION & PRIORITY CLAIM

This patent application claims the benefit of and priority to U.S. Provisional Patent Application No. 61/138,051, entitled SMART CARD REINFORCEMENT, and filed 16 Dec. 2008, which is hereby incorporated herein by reference as if fully set forth below. Embodiments of the present invention may also utilize technology disclosed in U.S. Pat. No. 7,278,025 and PCT Application Publication Number WO 2005/104704; both of these publications are hereby incorporated herein by reference as if fully set forth below.

### TECHNICAL FIELD

Embodiments of the present invention relate generally to portable verification devices, and more particularly, to reinforced smart cards, smart card components, verification cards, verification card components, and methods of making such items. Embodiments of the present invention may also be used to yield reinforced components for use in sensors, LCD displays, EL displays, OLEDs, indicators, solar cells, and batteries.

### BACKGROUND

Smart cards, which are also referred to as integrated circuit (IC) cards, typically include a microprocessor and memory on a plastic body, and are capable of data processing required for a specific purpose of each card. Smart cards range from simple memory-type smart cards storing user identification information to high-end smart cards with a sophisticated computational capacity. Typically, a card reader is used to read the stored information associated with the cardholder, such as a user name, account number, personal identification number (PIN), password, and the like. The card reader may be contact type or contactless type. Authentication is typically performed after information is read from the smart card by the card reader, and is typically performed by the card reader or other authentication device communicating with the card reader, such as a local or remote authentication sever.

Conventional smart cards are typically credit-card sized. For example, the ISO 7810 standard provides for various identification card formats ID-1, ID-2, ID-3, and ID-000. ID-1 cards are smart cards and are specified by the 7810 standard as being 85.60 mm long by 53.98 mm wide by 0.76 mm thick. Further, according to ISO 7813, smart cards have rounded corners with radii of 3.18 mm. Integrated circuits used in smart cards are typically much thinner than standard semiconductor wafer thicknesses. For example, with smart card thicknesses of 760 μm, integrated circuits used in smart cards are typically up to about 400 μm thick, while typical semiconductor wafers are about 650 μm thick. Therefore, semiconductor chips are typically made thinner or reduced in thickness prior to being used as part of a smart card.

What is needed, therefore, are smart cards systems and methods enabling and providing thin yet resilient end user devices. It is to the provision of such smart card devices, systems, and methods that the various embodiments of the present invention are directed. Embodiments of the present invention also provide reinforced cards in general and also used to provide components (such as an IC circuits and related wafers) for sensors, LCD displays, EL displays, OLEDs, indicators, solar cells, and batteries.

### BRIEF SUMMARY OF EXEMPLARY EMBODIMENTS

An exemplary method of making an integrated circuit chip includes: providing an integrated circuit wafer including a plurality of integrated circuits, the wafer being substantially disc-shaped and having a wafer perimeter, the wafer having a wafer bottom surface and a wafer top surface, the integrated circuits being disposed on the wafer top surface, the wafer bottom surface spanning a wafer bottom area; providing a stiffener having a stiffener top surface spanning a stiffener top area corresponding at least to a circuitry portion of the wafer top surface on which the integrated circuits are disposed; attaching the stiffener top surface to the wafer bottom surface to form a wafer/stiffener assembly; and physically separating the integrated circuits of the wafer/stiffener assembly by removing wafer material between the integrated circuits and stiffener material between regions of the stiffener underlying the integrated circuits.

Embodiments of such methods may include one or more of the following features. A method further includes applying a dicing tape to a bottom surface of the stiffener of the wafer assembly before physically separating the integrated circuits. A method further includes thinning the integrated circuit wafer before attaching the stiffener to the wafer. The thinning includes thinning the wafer to a thickness between about 50 μm and about 150 μm. The thinning includes thinning the wafer to a thickness of about 150 μm. The physically separating includes cutting the wafer assembly into rectangular pieces each containing one of the integrated circuits. The stiffener is attached to the wafer such that a portion of the wafer bottom surface corresponding to the circuitry portion is overlaid by the stiffener. The stiffener is attached to the wafer such that the stiffener overlays the entire wafer bottom surface.

An exemplary integrated circuit die includes: an integrated circuit layer comprising a semiconducting material and integrated circuit components occupying portions of a top surface of the semiconducting material, the integrated circuit layer having a substantially rectangular shape with substantially planar integrated circuit layer sides; and a stiffener layer attached to a bottom surface of the semiconductor material and having a substantially rectangular shape similar to the shape of the integrated circuit layer, the stiffener layer having substantially planar stiffener layer sides that are substantially coplanar with the integrated circuit layer sides.

Embodiments of such integrated circuit dice may include one or more of the following features. An integrated circuit die further includes an adhesive layer disposed between and connecting the integrated circuit layer and the stiffener layer, the adhesive layer having a substantially rectangular shape similar to the shape of the integrated circuit layer and the stiffener layer, the adhesive layer having substantially planar adhesive layer sides that are substantially coplanar with the integrated circuit layer sides and the stiffener layer sides. The integrated circuit layer, the stiffener layer, and the adhesive layer each include cut marks on their respective sides that are substantially continuous from the stiffener layer to the adhesive layer to the integrated circuit layer. The cut marks are substantially circular arcs.

Items and/or techniques described herein may provide one or more of the following capabilities. Improved integrated circuit chip resiliency in smart cards can be provided. Higher yield rates for integrated circuit chips for smart cards can be achieved.

Other aspects and features of embodiments of the present invention will become apparent to those of ordinary skill in the art, upon reviewing the following description of specific, exemplary embodiments of the present invention in conjunction with the accompanying figures. While features of the present invention may be discussed relative to certain embodiments and figures, all embodiments of the present invention can include one or more of the advantageous features discussed herein. In other words, while one or more embodiments may be discussed as having certain advantageous features, one or more of such features may also be used in accordance with the other various embodiments of the invention discussed herein. While discussion may, at times, focus on smart card applications, embodiments of the present invention can also be used in other applications or settings. Also, while exemplary embodiments may be discussed below as system or method embodiments it is to be understood that such exemplary embodiments can be implemented in various systems, and methods.

### BRIEF DESCRIPTION OF FIGURES

FIG. 1 is a schematic view of a smart card according to some embodiments of the present invention.

FIG. 2 is a schematic flow diagram of a process of thinning a wafer according to some embodiments of the present invention.

FIG. 3 is a schematic flow diagram of a process of attaching a stiffener to a thinned wafer according to some embodiments of the present invention.

FIG. 4 is a schematic diagram of a process of attaching dicing tape to a thinned, stiffened wafer according to some embodiments of the present invention.

FIG. 5 is a photographic flow diagram of a process of dicing a wafer according to some embodiments of the present invention.

FIG. 6 is a perspective view of a die including a thinned wafer portion and a stiffener portion according to some embodiments of the present invention.

### DETAILED DESCRIPTION OF PREFERRED & ALTERNATIVE EMBODIMENTS

To facilitate an understanding of the principles and features of the various embodiments of the invention, various illustrative embodiments are explained below. Embodiments of the present invention may be described below with reference to RFID reader applications. The embodiments of the invention, however, are not so limited. This patent specification describes, among other things, embodiments of techniques for making smart cards, embodiments of smart cards, and embodiments of semiconductor integrated circuit dice.

For example, a semiconductor integrated circuit wafer can be thinned by applying grinding tape to the wafer, grinding the wafer to a smaller thickness, exposing the tape to ultraviolet (UV) radiation, and removing the grinding tape from the wafer. A stiffener may be attached to the thinned wafer using an appropriate adhesive, such as an adhesive tape. Dicing tape may be applied to the wafer and stiffener combination, and the combination cut into dice using a wafer saw. The wafer saw may cut the wafer into dice without cutting through the dicing tape. The dicing tape may be stretched in order to separate the dice from one another. The dicing tape may be exposed to UV radiation to weaken a bond between the dicing tape and the wafer/stiffener combination. The individual dice may be separated from the dicing tape, e.g., using a die pick-up tool. Other embodiments, e.g., of integrated circuit dice, techniques for making integrated circuit dice, smart cards, etc., are within the scope of the disclosure.

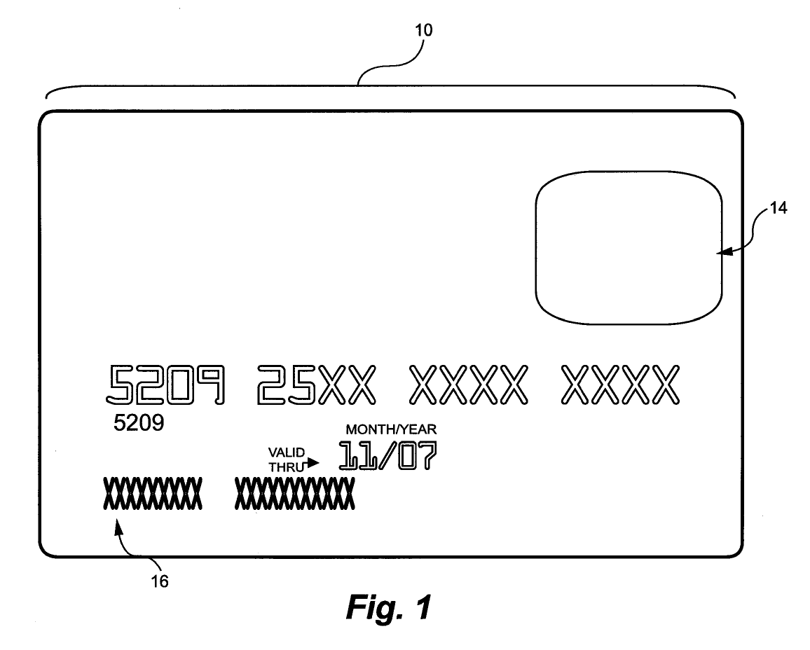

Referring now to the figures, wherein like reference numerals in some instances represent like parts throughout the views, exemplary embodiments of the present invention are described in detail. Referring to FIG. 1, a smart card 10 includes an integrated circuit module 12, a logo portion 14, and a name portion 16. The integrated circuit module 12 provides intelligence to the smart card 10 for performing various functions such as relaying information about an owner of the smart card 10. The module 12 may further be able to perform functions with information received by the module 12, or selectively provide information to an appropriate card reader in response to authenticating that the holder of the card 10 is the owner of the card 10. The logo portion 14 provides an identifier of the type of smart card, its use, etc. such as identifying it as a credit card, debit card, or other form of smart card.

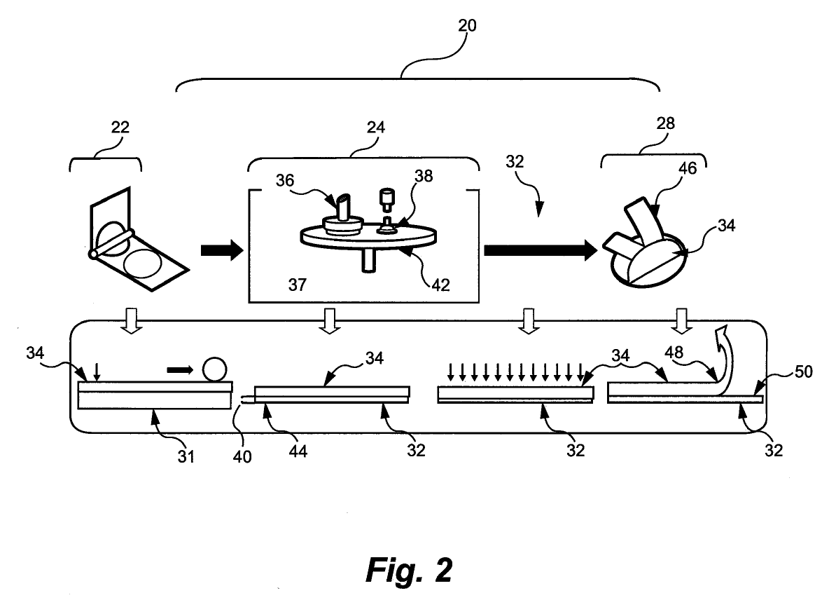

Referring to FIG. 2, a process 20 of thinning an integrated circuit semiconductor wafer 31 is shown. The process 20, however, is exemplary only and not limiting. The process 20 may be altered, e.g., by having stages added, removed, or rearranged.

At stage 22, the semiconductor wafer 31 has back-grind tape 34 attached to it. Here, for example, the tape 34 is laminated to the wafer 31 by disposing the tape 34 over the wafer 31 and rolling the tape 34 into contact with the wafer 31 to firmly adhere the tape 34 to the wafer 31. Other techniques for adhering the tape 34 to the wafer 31 may be used, including other techniques for pressing the tape 34 against the wafer 31. The adhesion provided between the tape 34 and the wafer 31 is strong, allowing the wafer 31 to be manipulated as described herein.

At stage 24, the wafer 31 is ground and polished to thin the wafer 31, forming a thinned wafer 32. The wafer 31 is attached to a spindle 36, e.g., by a strong vacuum applied to the tape 34, and the spindle 36 with the attached wafer 31 is submersed in deionized water 37. The spindle 36 is rotated, thereby rotating the combination of the wafer 31 and the tape 34, and the wafer 31 is moved into contact with a grinding member 38 that is also submersed in the deionized water 37. The wafer 31 is forced against the grinding member 38 until a thickness 40 of the wafer is reduced to approximately a desired dimension, e.g., approximately 150 μm. The wafer 32 is further forced against a polishing plate 42 (also in the water 37) in order to smooth a surface 44 of the wafer 32 and further refine the thickness 40 to the desired dimension. Thus, preferably the wafer thickness 40 is slightly larger than the ultimate desired dimension after the grinding and before the polishing.

At stage 26, the back-grind tape 34 undergoes UV irradiation. The tape 34 is exposed to UV radiation to weaken the adhesion between the tape 34 and the wafer 32.

At stage 28, the back-grind tape 34 is separated from the wafer 32. Here, for example, removing tape 46 is attached to the back-grind tape 34, providing a strong bond between the tape 46 and a top surface 48 of the tape 34. The removing tape 46 is peeled to pull the back-grind tape 34 away from a top surface 50 of the wafer 32.

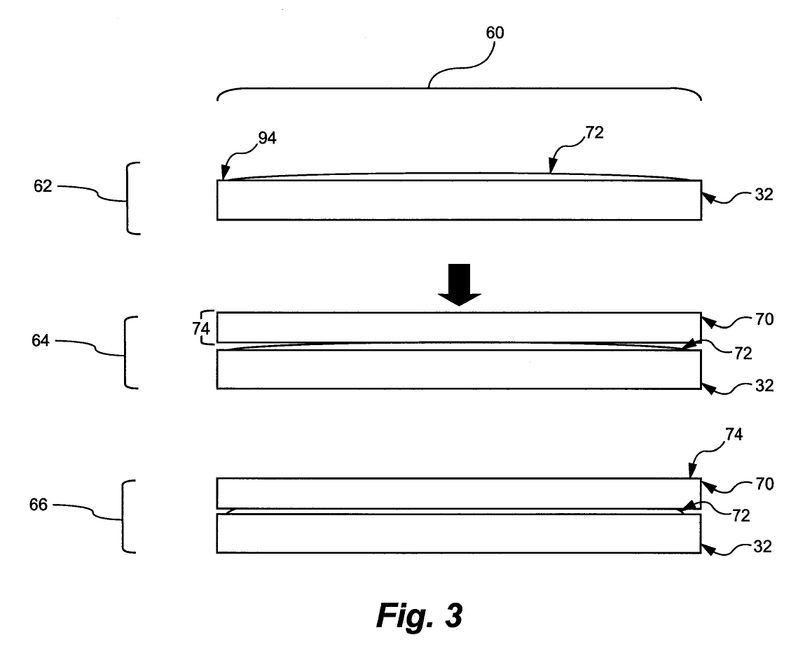

Referring to FIG. 3, a process 60 of attaching a stiffener 70 to the wafer 32 includes the stages shown. The process 60, however, is exemplary only and not limiting. The process 60 may be altered, e.g., by having stages, or portions thereof, added, removed, or rearranged.

At stage 62, an adhesive 72 is applied to the bottom surface 44 of the thinned wafer 32. Here, the adhesive 72 is preferably a highly-adhesive tape. For example, tape model AWD220 made by Ace Industries Co., Ltd. of Chowol-Myeon, Gwangju-Si, Gyeonggi-Do, Korea, may be used. One currently preferred adhesive is a 3M three bond, TESA, tape.

Other appropriate adhesives may, however, be used for the adhesive 72. For examples, other adhesive alternatives include double sided tape, EVA, Silicone, Epoxy, acrylic resin, or Wax. Current preferred embodiments can include double sided tape having a bonding layer, being made of thermal polymerizing material, such as epoxy copolymer. The epoxy copoloymer can be sintered, coated or laminated on the top of adhesive layer. In addition, the epoxy copoloymer can be made of acrylic copolymer. The copoloymer can be formed on the surface of an interlayer, such as Polyolefin.

Adhesives used in accordance with embodiments of the present invention can also have other aspects and features. For example, adhesive can be formed in a tape or preformed sheet. In some embodiments, adhesive can be coated or sprayed onto another surface. Thickness of the adhesive can range between about 5 microns to about 50 microns. Currently preferred embodiments utilize a thickness of about 20 microns. Adhesive can be applied in many different manners include pressing, heat, UV radiation, oxygen free environment. Currently preferred arrangements include pressing at a temperature ranging between 90 degrees Celsius and 110 degrees Celsius.

At stage 64, the stiffener 70 is attached to the wafer 32 using the adhesive 72. The stiffener 70 is moved into contact with the adhesive 72, with the stiffener 70 being substantially parallel to the wafer 32. The stiffener 70 preferably has approximately the same outer dimensions as the wafer 32 (about a 1:1 ratio), e.g., being circular with a diameter of approximately eight inches. The stiffener 70, however, need not have the same shape or dimensions as the wafer 32. The stiffener 70 is preferably made of engineered SUS (Steel Use Stainless) or Kovar® (made by Carpenter Technology Corporation of Wyomissing, Pa.), although other materials such as polyimide, Kevlar, metal, glass, epoxy, various forms of plastic, etc. may be used. Kovar is a nickel-cobalt ferrous alloy compatible with the thermal expansion characteristics of borosilicate glass (about 5×10⁻⁶/K between 30° C. and 200° C., to about 10×10⁻⁶/K at 800° C.). Other materials, e.g., other iron-nickel alloys, with similar thermal expansion characteristics may be used. Here, with the stiffener 70 being made of SUS or Kovar, the stiffener 70 has a length of about 16.81 mm, a width of about 13.37 mm, and a thickness 74 of approximately 200 μm, although stiffeners of other dimensions may be used.

Stiffners used in accordance with embodiments of the present invention can also have other aspects and features. For example, stiffner materials can include Polyimide, Poly carbonate (PC), SUS 304, Kovar, FR4 (hard PCB), Epoxy, Acrylic resin, and/or Photo polymerizing polymers. Stiffner thickness can range from about 0.05 mm to about 0.2 mm. Other materials and thicknesses may also be desired depending upon specific applications.

At stage 66, the adhesion of the stiffener 70 to the wafer 32 is strengthened. The stiffener 70 is impelled into close contact with the wafer 32, with the adhesive 72 between the wafer 32 and the stiffener 70. The adhesive 72 is preferably distributed substantially entirely across the wafer 32, extending in close proximity to a perimeter of the wafer 32 encompassing or overlaying all regions of the wafer 32 that will be made into individual dice. The adhesive 72 may extend all the way to the perimeter of the wafer 32, and may even extend outside of the perimeter of the wafer 32. The stiffener 70 adhered to the wafer 32 by the adhesive 72 forms a wafer assembly 74.

As mentioned above, embodiments of the present invention can also be used in various components where reinforcement is desired. For example, one or more of the following items can be protected via reinforcement (according to embodiments of the present invention): silicon wafers, glass substrates, plastic substrates, Poly carbonates, and tempered glass. Devices protected with embodiments of the present invention can include sensor, LCD displays, EL displays, OLEDs, indicators, solar cells, and/or batteries.

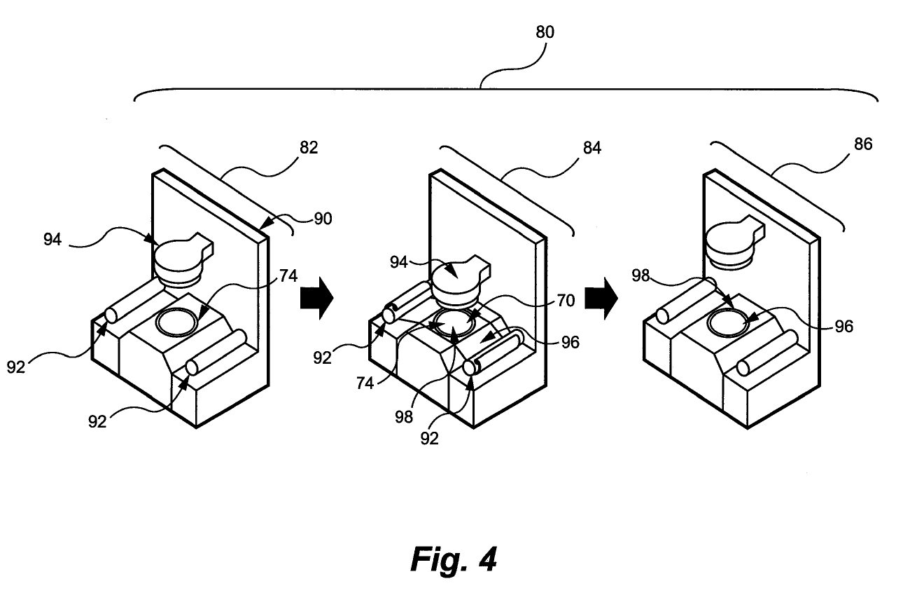

Referring to FIG. 4, a process 80 of preparing the wafer assembly 74 for separation into individual dice includes the stages shown. The process 80, however, is exemplary only and not limiting, and may be altered from the specific stages shown and described. Dicing tape is not shown on tape rollers in stages 82 or 86 for clarity, but this tape may be present during either or both of these stages.

At stage 82, the wafer assembly 74 is positioned in a tape mount apparatus 90. The assembly 74 is positioned between two rollers 92 and beneath a tape cutter 94.

At stage 84, dicing tape 96 is placed over the wafer assembly 74. The dicing tape 96 is stretched between the rollers 92 over and on top of the wafer assembly 74, specifically over the stiffener 70. The tape 96 is pulled into contact with a bottom surface 98 of the stiffener 70.

At stage 86, the tape 96 is cut. The tape cutter 94 is moved downwardly toward the wafer assembly 74 to cut the tape 96 about the perimeter of the wafer assembly 74 and to push the tape 96 into contact with the bottom surface 98 of the stiffener 70 to adhere the tape 96 to the wafer assembly 74. The wafer assembly 74, with the tape 96 attached to the assembly 74, can be removed.

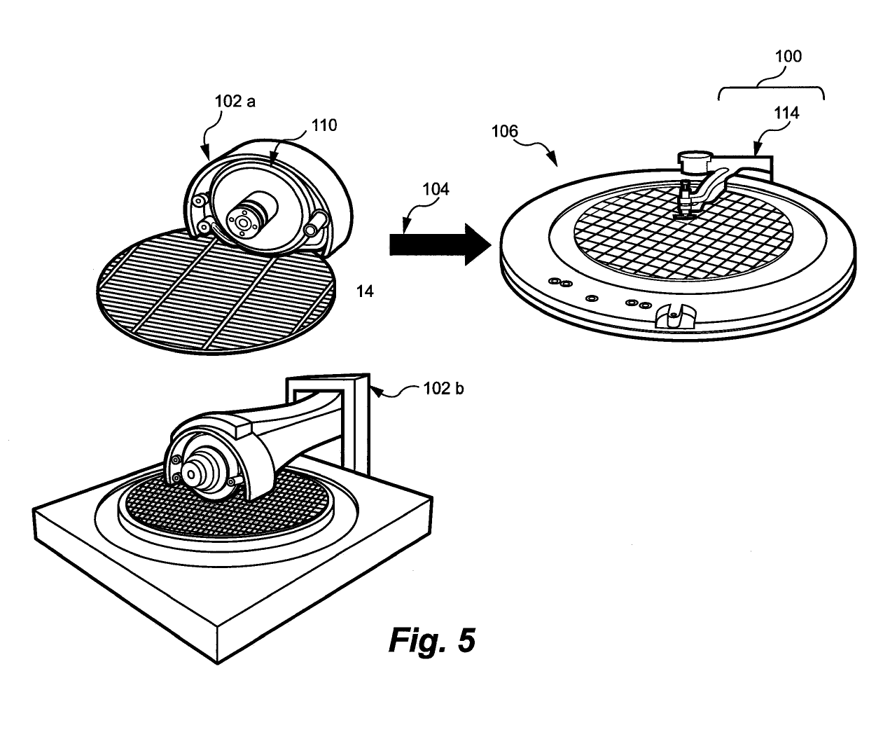

Referring to FIG. 5, a process 100 of creating and removing individual die from the wafer assembly 74 includes this stage as shown. The process 100, however, is exemplary only and not limiting. The process 100 may be altered, e.g., by having stages, or portions thereof, added, removed, or rearranged.

At stages 102A and 102B, a saw blade 110 is positioned over the wafer assembly 74 backed by the dicing tape 96 (not shown), and rotated and pushed through the wafer assembly 74 to cut the wafer 32, the stiffener 70, and the adhesive 72, but not the tape 96 (at least not completely through). The wafer assembly 74 is cut in two directions to separate the wafer assembly 74 into rectangular dice. Other alternative dicing methods include Sawing, laser cutting, Polishing, wire cutting, water cutting, super sonic cutting.

At stage 104, the individual dice 112 are separated from the dicing tape 96. The dicing tape 96 is exposed to UV radiation to weaken the adhesion between the dicing tape 96 and the stiffener 74.

At stage 106, the individual dice 112 are removed from the dicing tape 96. The dicing tape 96 can be stretched to provide separation between the dice 112 from one another. A die or chip pick-up tool 114 is used to lift the individual dice 112 away from the dicing tape 96 and move the dice 112 to an appropriate location.

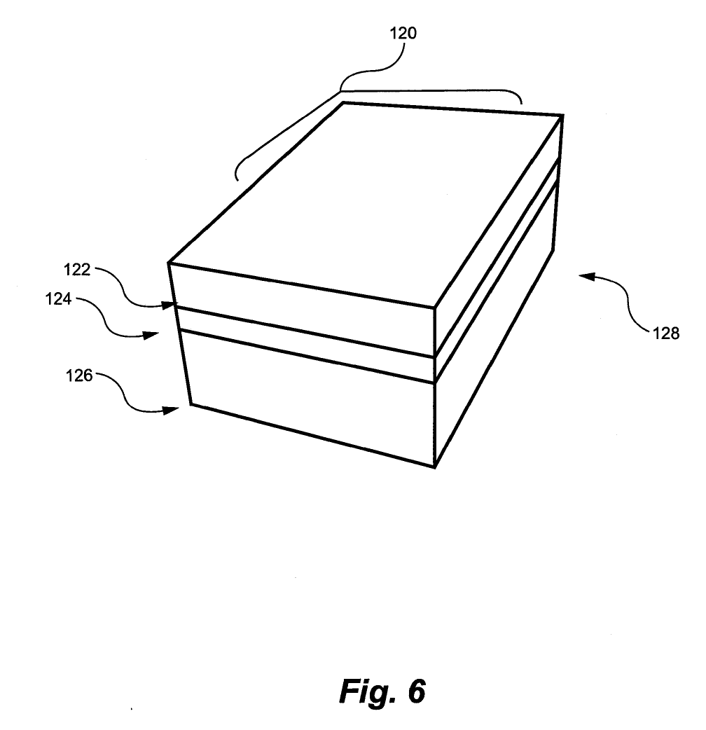

Referring to FIG. 6, an exemplary separated die 120 includes a semiconductor circuitry portion 122 of the wafer 32, an adhesive portion 124, and a stiffener portion 126. The die 120 as shown is rectangular, being approximately square. The semiconductor portion 120, adhesive portion 124, and stiffener portion 126 all have similar perimeter shapes and dimensions, having their edges be substantially coplanar. The portions 122, 124, and 126 thus provide portions of common edges of the die 120. The semiconductor portion 122, adhesive portion 124, and stiffener portion 126 each have their respective edges cut by the saw blade 110, and thus the portions 122, 124, and 126 are coextensive (or substantially coextensive). The saw blade 110 leaves cut marks 128 of circular or substantially-circular shape (possibly not exactly circular due to the linear travel of the saw blade 110) that are substantially continuous or collinear (albeit of curved lines) across the three layers 122, 124, 126. The cut marks 128 are thus approximately circular arcs.

The embodiments of the present invention are not limited to the particular formulations, process steps, and materials disclosed herein as such formulations, process steps, and materials may vary somewhat. Moreover, the terminology employed herein is used for the purpose of describing exemplary embodiments only and the terminology is not intended to be limiting since the scope of the various embodiments of the present invention will be limited only by the appended claims and equivalents thereof.

Other embodiments are within the scope of the description and the claims. The arrangements of components shown are for purposes of illustration and other combinations, additions, arrangements, and the like are possible and within the scope of the description and claims. For example, the adhesive 72 may be applied to the wafer 32 and/or the stiffener 70 and the wafer 32 and the stiffener 70 pushed together to adhere the wafer 32 to the stiffener 70 and vice versa.

Therefore, while embodiments of the invention are described with reference to exemplary embodiments, those skilled in the art will understand that variations and modifications can be effected within the scope of the invention as defined in the appended claims. Accordingly, the scope of the various embodiments of the present invention should not be limited to the above discussed embodiments, and should only be defined by the following claims and all equivalents.

I claim:

1. A method of making a reinforced integrated circuit chip that can be used in a smart card, the method comprising:
providing an integrated circuit wafer including a plurality of integrated circuits, the wafer being substantially disc-shaped and having a wafer perimeter, the wafer having a wafer bottom surface and a wafer top surface, the integrated circuits being disposed on the wafer top surface, the wafer bottom surface spanning a wafer bottom area;
providing a stiffener having a stiffener top surface spanning a stiffener top area corresponding at least to a circuitry portion of the wafer top surface on which the integrated circuits are disposed;
attaching the stiffener top surface to the wafer bottom surface to form a wafer/stiffener assembly; and
physically separating the integrated circuits of the wafer/stiffener assembly by removing wafer material between the integrated circuits and stiffener material between regions of the stiffener underlying the integrated circuits.

2. The method of claim 1 further comprising applying a dicing tape to a bottom surface of the stiffener of the wafer assembly before physically separating the integrated circuits.

3. The method of claim 1 further comprising thinning the integrated circuit wafer before attaching the stiffener to the wafer.

4. The method of claim 3 wherein the thinning comprises thinning the wafer to a thickness between about 50 μm and about 150 μm.

5. The method of claim 4 wherein the thinning comprises thinning the wafer to a thickness of about 150 μm.

6. The method of claim 1 wherein the physically separating comprising cutting the wafer assembly into rectangular pieces each containing one of the integrated circuits.

7. The method of claim 1 wherein the stiffener is attached to the wafer such that a portion of the wafer bottom surface corresponding to the circuitry portion is overlaid by the stiffener.

8. The method of claim 7 wherein the stiffener is attached to the wafer such that the stiffener overlays the entire wafer bottom surface.

9. An integrated circuit die that can be used in a smart card, the die comprising:
an integrated circuit layer comprising a semiconducting material and integrated circuit components occupying portions of a top surface of the semiconducting material, the integrated circuit layer having a substantially rectangular shape with substantially planar integrated circuit layer sides; and
a stiffener layer attached to a bottom surface of the semiconductor material and having a substantially rectangular shape similar to the shape of the integrated circuit layer, the stiffener layer having substantially planar stiffener layer sides that are substantially coplanar with the integrated circuit layer sides.

10. The integrated circuit die of claim 9 further comprising an adhesive layer disposed between and connecting the integrated circuit layer and the stiffener layer, the adhesive layer having a substantially rectangular shape similar to the shape of the integrated circuit layer and the stiffener layer, the adhesive layer having substantially planar adhesive layer sides that are substantially coplanar with the integrated circuit layer sides and the stiffener layer sides.

11. The integrated circuit die of claim 10 wherein the integrated circuit layer, the stiffener layer, and the adhesive layer each include cut marks on their respective sides that are substantially continuous from the stiffener layer to the adhesive layer to the integrated circuit layer.

12. The integrated circuit die of claim 11 wherein the cut marks are substantially circular arcs.

13. In an device comprising an integrated circuit having one or more semiconductor portions, a system to reinforce one of more of the semiconductor portions, the system comprising a stiffener material having an outer peripheral dimension that matches up to a first semiconductor portion wherein the stiffener is laminated to the first semiconductor portion so that the stiffener provides mechanical reinforcement to the entire area of the first semiconductor portion, and wherein an adhesive material is disposed between the first semiconductor portion and the stiffner to bind the first semiconductor portion and the stiffener together.

14. The system of claim 13, wherein the adhesive material comprises a preformed sheet that includes a plurality of preformed adhesive portions.

15. The system of claim 13, wherein the first semiconductor portion, the stiffner, and the adhesive all have substantially the same outer peripheral shape.
